(19) United States
(12) Patent Application Publication
(10) Pub. No.: US 2003/0189818 A1
(43) Pub. Date: Oct. 9, 2003

(54) Substrate cover assembly

(76) Inventors: Michael A. Brooks, Sacramento, CA (US); James D. Hensley, Rocklin, CA (US); Michael J. Greenside, Granite Bay, CA (US)

Correspondence Address: HEWLETT-PACKARD COMPANY, Intellectual Property Administration, P.O. Box 272400, Fort Collins, CO, 80527-2400, US

(21) Appl. No.: 10/117,025

(22) Filed: Apr. 4, 2002

(51) Int. Cl. H05K 7/14; H05K 7/18

(52) U.S. Cl. 361/796

(57) ABSTRACT

A substrate cover assembly is disclosed. In one embodiment, the present invention is comprised of a cover element adapted to be removably-coupleable with a substrate. The present embodiment is further comprised of at least one openable portion coupled with the cover element. Beneficially, the openable portion is adapted to allow access to a portion of the substrate.

### TECHNICAL FIELD

The present claimed invention relates to the field of printed circuit assemblies (PCAs). More specifically, the present claimed invention relates to substrate covers employed in conjunction with PCAs.

### BACKGROUND ART

Presently, printed circuit assemblies (PCAs) are comprised of a substrate (e.g., PC board) with associated microcircuits. Typically, PCAs are used in conjunction with chassis structures to allow a large amount of processing ability to fit into a small space. In general, the chassis structure may contain a multiplicity of PCAs operating independently, in conjunction, or as a portion of a larger network. Normally, the PCA is attached to the chassis type structure in conjunction with very specific standards. Typically, PCA attaching standards include, for example, the compact peripheral component interconnect (CPCI) standard, and the VersaModular Eurocard (VME) standard.

Typically, PCAs fabricated to one of the above mentioned standards (e.g., CPCI or VME) are used in the chassis type structure in conjunction with a card guide. One deleterious effect is damage to components located on the PCA during insertion or extraction with the card guide. For example, misalignment of connector pins, dislodging of solder, and in extreme cases a broken PCA or chassis may occur. In addition, due to the compact nature of the chassis, PCA cards are often located very close together. In some situations, such close proximity with regard to PCAs may result in a short between two or more PCAs or their associated microcircuits. Another deleterious effect results from damage to components located on the PCA during normal handling of the PCA. For example, the PCA may be scraped on a counter which may cause the solder or connector pins to become dislodged.

At present, one approach to fix the problems described above is to use a cover to protect the substrate. In general, these substrate covers may include a front side (component) cover and/or a backside (solder-side) cover. The substrate covers, normally fabricated from plastic, are intended to prevent damage to components, possible electrical shorting, and other deleterious effects when installing and/or extracting the PCA from the card guides, as well as during handling, and regular PCA operations.

The allowance for the solder-side cover for a PCA is provided in section 4.1.8 of the CPCI core specification. Typically, the covers are permanently or semi-permanently attached to the PCA with screws. By fixedly-attaching the covers, manufacturers ensure that the proper level of protection for a chassis system utilizing PCAs is provided. However, there are times when a PCA contains serviceable components beneath the substrate cover. During such a time, the components must be accessed to be upgraded, replaced, or the like. Therefore, a user would need to remove the attached substrate cover.

In many cases, the user may not have the proper tools or parts to remove the cover. Moreover, once the cover is removed, the user may not have the proper tools or parts to correctly replace the cover. In addition, portions of the hardware may be lost, the cover may be forgotten, or the process may become to time consuming and the user may decide not to replace the cover at all. If the PCA card is replaced without the beneficial protection of the substrate cover, it is possible that an electrical short, similar to that stated above, will occur within a portion of the PCA. Furthermore, an electrical short within a portion of the PCA may cause the PCA to explode, or even start a fire within the chassis structure.

Such damage to the PCA and the chassis would be an extremely expensive problem. Not only would the entire chassis require replacement, any plurality of other PCAs attached to the chassis may also require replacement. In addition, the system operating in conjunction with the chassis would be out of operation. Such “down time” may result in a significant amount of monetary loss.

A different maintenance option may be the utilization of a technician to service any components located beneath the substrate cover. However such a method is expensive, time-consuming, and lacks the desired “Design for Manufacturability.”

### DISCLOSURE OF THE INVENTION

The present invention provides a substrate cover method and apparatus which reduces damage to components located on a substrate. The present invention also provides a substrate cover method and apparatus which achieves the above accomplishment and which allows access to serviceable or replaceable components without removal of the substrate cover. The present invention further provides a substrate cover method and apparatus which achieves the above accomplishment and which reduces the time needed to access serviceable or replaceable components. The present invention also provides a substrate cover method and apparatus which achieves the above accomplishments and which can be adapted to readily interface with industry standard components and meet industry standard specifications.

Specifically, a substrate cover assembly is disclosed. In one embodiment, the present invention is comprised of a cover element adapted to be removably-coupleable with a substrate. The present embodiment is further comprised of at least one openable portion coupled with the cover element. Beneficially, the openable portion is adapted to allow access to a portion of the substrate.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1A is a front view of an exemplary substrate cover assembly in accordance with one embodiment of the present claimed invention.

FIG. 1B is a top view of an exemplary substrate cover assembly in accordance with one embodiment of the present claimed invention.

FIGS. 2A-2C are views of exemplary substrate cover assemblies in accordance with one embodiment of the present claimed invention.

FIG. 3 is a perspective view of an exemplary substrate cover assembly coupled with a bulkhead and a substrate in accordance with one embodiment of the present claimed invention.

FIG. 4 is a flow chart of steps performed in accordance with one embodiment of the present claimed substrate cover assembly.

The drawings referred to in this description should be understood as not being drawn to scale except if specifically noted.

### BEST MODES FOR CARRYING OUT THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, the present invention may be practiced without these specific details. In other instances, well-known methods, procedures, components, and circuits have not been described in detail as not to unnecessarily obscure aspects of the present invention.

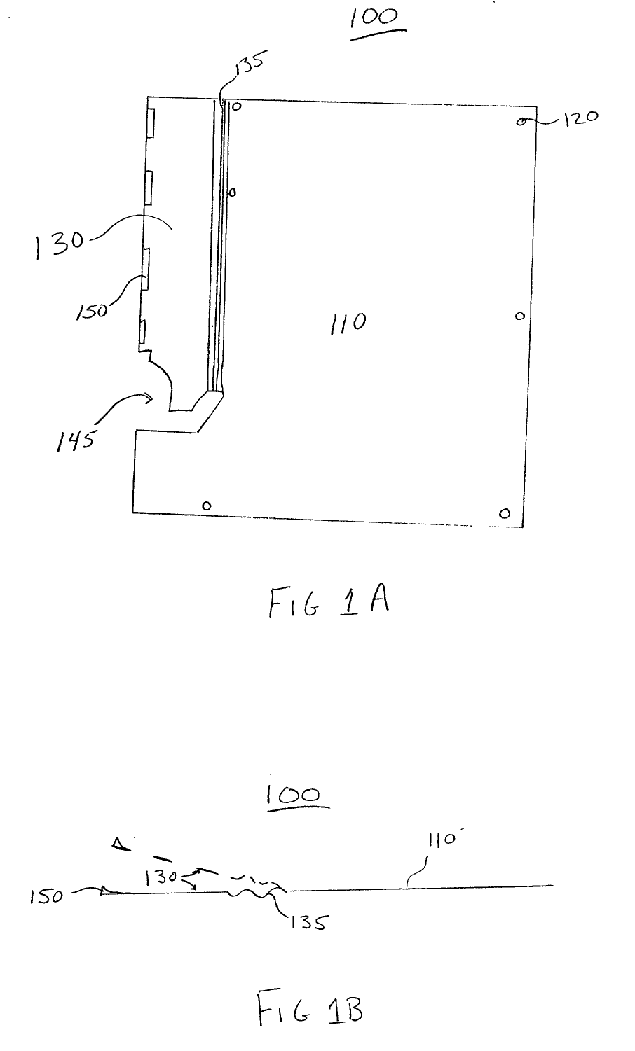

With reference now to FIG. 1A, a front view of an exemplary substrate cover assembly 100 in accordance with one embodiment of the present claimed invention is shown. The following discussion will begin with a detailed description of the physical characteristics of the present substrate cover assembly 100. The discussion will then contain a detailed description of the use and operation of the present substrate cover assembly 100. Referring now to the physical characteristics of the present substrate cover assembly 100, in the present embodiment, substrate cover assembly 100 includes cover element 110. Importantly, as will be discussed in detail herein, in one embodiment, cover element 110 is formed having dimensions and characteristics which are in compliance with an industry standard such as, for example, the compact peripheral component interconnect (CPCI) standard, the VersaModular Eurocard (VME) standard, and the network equipment building systems (NEBS) standard.

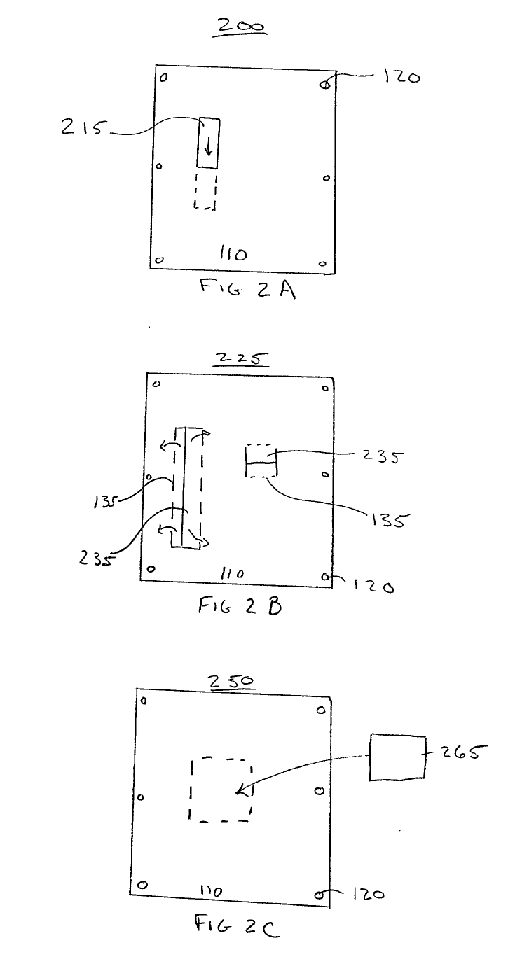

Referring still to FIG. 1A, substrate cover assembly 100 also includes openable portion 130. Specifically, openable portion 130 is adapted to be coupled with cover element 110. Openable portion 130 is ultimately employed to allow access to, or selectively expose portions of, material underlying cover element 110. Additionally, in one embodiment, openable portion 130 includes a hinged portion 135. Importantly, as will be discussed in detail herein, openable portion 130 is formed having dimensions and characteristics which are in compliance with an industry standard such as, for example, the CPCI standard, and the VME standard. Also, although a hinged portion 135 is specifically mentioned as the type of openable portion 130 utilized by cover element 110, the present invention is well suited to use with various other types of openable portions including, for example, a sliding portion, a window portion, a removable portion, and the like. FIGS. 2A-2C include other embodiments of substrate cover assembly 200, 225, and 250, in accordance with the present invention in which the openable portion is comprised of sliding portion 215, window portion 235, and removable portion 265. Although these particular embodiments are shown, the present invention is well suited to any type of opening which allows access to the substrate underneath cover element 110 without requiring removal of cover element 110. However, for purposes of brevity and clarity each of the numerous possibilities of openable portions are not shown in the present Figures.

With reference now to FIGS. 1A-1B and 2B, openable portion 130 as well as window portion 235 are coupled with cover element 110 via a hinge. One example of the hinge is a “living hinge 135” as shown in FIGS. 1A-1B and 2B. Specifically, one of the many requirements outlined by NEBS is the flame retardant (suppression) standard UL94V-0 for plastics. In general, plastics that meet the NEBS requirements are often to brittle for a single pivot hinge. Therefore, a hinge design was required to ensure that openable portion 130 and window portion 235 would not break or crack with respect to cover element 110. In one embodiment, the hinged region (e.g., 135) of openable portion 130 and/or window portion 235 may be comprised of several compound curvatures (or bends). Therefore, each bend only needs to move a few degrees but the openable portion 130 and/or window portion 235 will move a sufficient amount to gain access to the components thereunder. For example, as each bend moves slightly, the sum of the individual bends will move enough to allow a user to access the desired components covered by openable portion 130 and/or window portion 235. Thus, the hinge 135 utilized in both openable portion 130 and/or window portion 235 (of FIGS. 1A-1B and 2B) does not stress or crack.

With reference again to FIG. 1A, substrate cover assembly 100 of the present embodiment also includes a finger hole 145 cut into a portion of openable portion 130. Finger hole 145 is employed to assist a user in opening openable portion 130. The present embodiment is also well suited to an embodiment in which openable portion 130 does not include a finger hole 145.

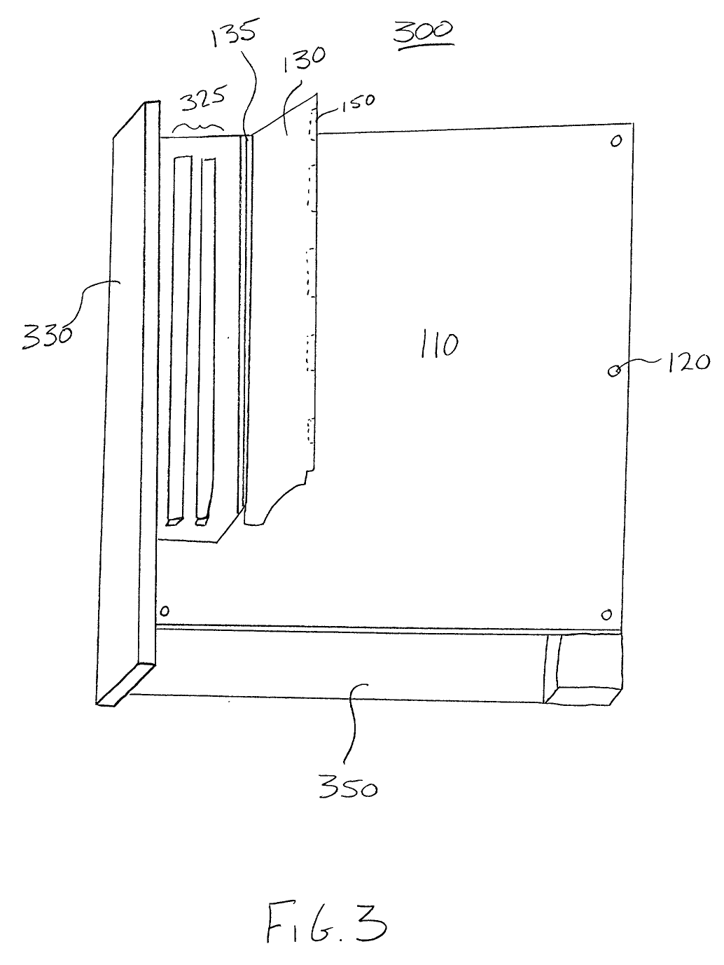

Substrate cover assembly 100 of the present embodiment also includes a tuck slot 150 in a portion of openable portion 130. Tuck slots 150 are employed to ensure that openable portion 130 is securely held in a closed position. In one embodiment, tuck slots 150 allow openable portion 130 to be secured behind a panel bulkhead (e.g., 330 of FIG. 3).

Referring still to FIG. 1A, substrate cover assembly 100 also includes an attaching device 120 that is adapted to be removably-coupleable to a substrate. In one embodiment, attaching device 120 is comprised of a plastic rivet. Attaching device 120 is ultimately employed to removably couple cover element 110 to a substrate, such that removal of cover element 110 from the substrate to which it is attached is possible. In one embodiment, the substrate is a printed circuit board (PCB) 350. Additionally, attaching device 120 is an attaching device formed having dimensions and characteristics which are in compliance with an industry standard such as, for example, the CPCI standard, and the VME standard. Also, although a plastic rivet is specifically mentioned as the substrate-attaching device 120 in the present embodiment, the present invention is also well suited to use with various other types of attaching devices including, for example, screws, snaps, adhesive, and the like.

With reference now to FIGS. 2A-2C, as stated above and described in detail herein, various other types of openable portions including, for example, a sliding portion 215, a window portion 235, a removable portion 265, and the like are illustrated. In one embodiment, as shown in FIG. 2B, a plurality of openable portions such as window portions 235 may be included within cover element 110. Additionally, cover element 110 may include a plurality of openable portions of differing style. For example, cover element 110 may include an openable portion 130 with hinge 135 and a window portion 235. However, for purposes of brevity and clarity each of the numerous possibilities of openable portions are not shown in the present Figures.

### Use and Operation

The following is a detailed description of the use and operation of the present substrate cover assembly 300. With reference to FIG. 3, in one embodiment of the present invention, an openable portion (e.g., hinge 130, slide 215, window 235, removable 265) is coupled with a substrate cover 110. Generally speaking, substrate cover assembly 300 is an assembly for attaching a substrate cover 110 to a substrate (e.g., PCB 350). The resulting assembly (e.g., assembly 300 of FIG. 3) is a complete printed circuit assembly (PCA) with substrate cover 110 designed to protect the PCA 300 and any components thereon during insertion with and removal from a computer chassis. The resulting assembly (e.g., assembly 300 of FIG. 3) is also designed to protect the PCA 300 and any components thereon while the assembly is active therein.

With reference still to FIG. 3, an openable portion 130 with hinge 135 is shown coupled to cover element 110. In one embodiment, substrate 350 is comprised of two PCBs stacked one above the other in an “opposing daughter card” configuration. For example, substrate 350 may be a PCA which takes up two slots in a chassis. Wherein, one PCA is placed in normal orientation, while another PCA is placed facing the first. The second PCA may have less height, fewer components, and gaps to allow for larger components (e.g., dual in-line memory modules, or the like) on the first PCA. Therefore, the two PCA's make a “sandwich” wherein only a portion of the top PCA is coupled to the bottom PCA or bulkhead 330.

In the above arrangement, both sides of substrate 350 have their solder-sides facing outward. Therefore, during insertion and extraction, it is possible that the solder-sides will be scraped along any adjoining blades. If that happens, damage to the components or solder pathways on assembly 300 may occur. Additionally, due to the increased size of assembly 300, during operation within the chassis, electrical interaction may occur between assemblies such as two assembly 300s located in adjoining slots. In order to protect assembly 300, cover element 110 is coupled with substrate 350 and acts as a barrier against mechanical damage and electrical interaction.

In one embodiment, cover element 110 is removably-coupleable with substrate 350 utilizing attaching device 120. Furthermore, a plurality of attaching devices 120 may be used in conjunction to removably-couple cover element 110 with substrate 350 such that removal of cover element 110 from substrate 350 is possible. As stated herein, attaching device 120 may be a rivet, screw, snap, adhesive, or the like, which can removably-couple cover element 110 with substrate 350. Additionally, attaching device 120 may be plastic, metal, or polymer. Although a specific pattern for attaching device 120 placement is shown in FIG. 3, any plurality of patterns may be utilized with attaching device 120. The present pattern is shown merely for purposes of brevity and clarity.

Importantly, as stated herein, cover element 110 has an openable portion 130. In one embodiment, as shown in FIG. 3, openable portion 130 is placed over a region of assembly 300 to which a user may desire access. In the present embodiment, the desired region contains dual in-line memory modules (DIMMs) 325. However, the region may be any portion of user serviceable components that may be accessed underneath cover element 110 on a relatively frequent basis, wherein it is disadvantageous to remove cover element 110, but protection of the components is desired. For example, the accessible portion may contain a super-cap with a short life span, DIMMs (e.g., 325), or the like. Although one openable portion 130 is shown, as stated above, a plurality of openable portions 130 may be used. One openable portion 130 is shown in the present embodiment merely for purposes of brevity and clarity.

With reference still to FIG. 3, openable portion 130 includes tuck slots 150. In one embodiment, tuck slots 150 are utilized to securely hold openable portion 130 in a closed position. This is accomplished by tucking openable portion 130 underneath the lip of bulkhead 330. Tuck slots 150 then removably-couple with bulkhead 330 thus ensuring the cover will not open during normal operation.

Therefore, when a user desires access to any components underneath the cover element 110, the operation is simplified. Specifically, in one embodiment, the user first removes the PCA 300 from the chassis. Then openable portion 130 is opened and access to the underlying components (e.g., DIMMs 325) is established. Upon completion of the desired maintenance, the user then closes the “living hinge” (e.g., openable portion 130) and replaces tuck slots 150 underneath bulkhead 330. The entire PCA 300 is then reinserted into the chassis. Thus, access to a desired component is obtained without requiring removal of the complete cover element 110.

Referring still to FIG. 3, cover element 110 may further be utilized in any number of PCA card situations. The use of a two card PCA embodiment is merely for purposes of clarity. For example, in a single card PCA situation, cover element 110 would still protect the solder pathways on the back of the PCB as well as any components residing thereon. In addition, access to any components on the PCA may be similar to that described herein (e.g., supercap overheat, component exchange, etc.).

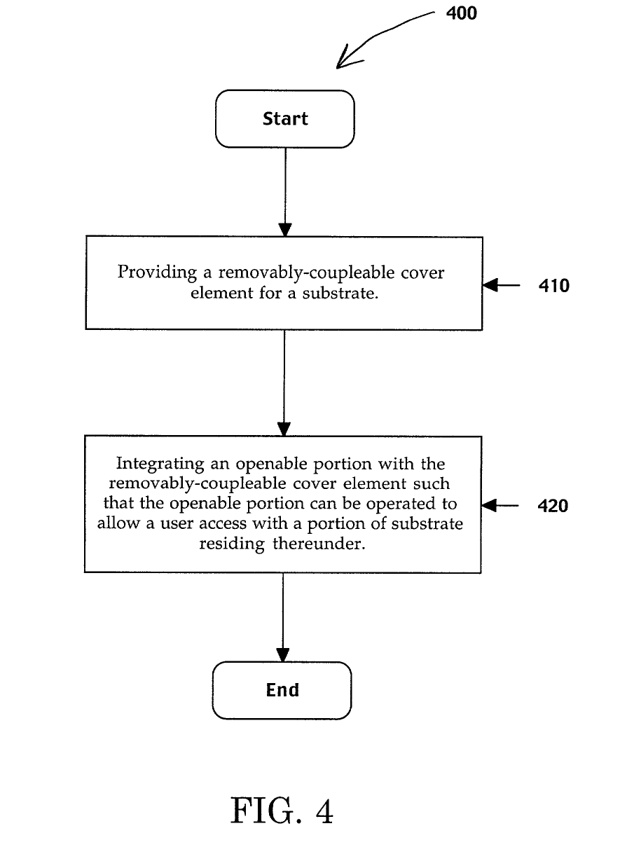

With reference now to FIG. 4, a flow chart 400 summarizing the steps performed in accordance with one embodiment of the present invention is shown. At step 402, the present embodiment provides a removably-coupleable cover element (e.g., 110) for a substrate (e.g., 350). As described in detail above, cover element 110 is adapted to removably couple with a substrate 350 such that damage to substrate 350 with respect to a chassis or another substrate is reduced.

Next, at step 404, the present embodiment integrates an openable portion (e.g., hinge 130, slide 215, window 235, removable 265) with the removably-coupleable cover element (e.g., 110). In so doing, the present embodiment provides an openable portion (e.g., hinge 130, slide 215, window 235, removable 265) which can be operated to allow a user access with a portion of substrate (e.g., 350) residing thereunder. Beneficially, the present embodiment reduces the possibility of damage to substrate 350 (e.g., a PCA). As a result, the probability for electrical problems caused by inserting assembly 300 into a chassis is also reduced. In addition, the present embodiment allows simplified attachment of a cover element (e.g., 110) to a substrate 350. Thus, the present invention achieves a “Design for Manufacturability” lacking in the prior art. Additionally, by reducing the labor requirements, the present embodiment provides a more efficient, less expensive substrate cover assembly (e.g., 100).

Thus, the present invention provides a substrate cover method and apparatus which reduces damage to components located on a substrate. The present invention also provides a substrate cover method and apparatus which achieves the above accomplishment and which allows access to serviceable or replaceable components without removal of the substrate cover. The present invention further provides a substrate cover method and apparatus which achieves the above accomplishment and which reduces the time needed to access serviceable or replaceable components. The present invention also provides a substrate cover method and apparatus which achieves the above accomplishments and which can be adapted to readily interface with industry standard components and meet industry standard specifications.

The foregoing descriptions of specific embodiments of the present invention have been presented for purposes of illustration and description. They are not intended to be exhaustive or to limit the invention to the precise forms disclosed, and modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

1. A substrate cover assembly comprising:
a cover element adapted to be removably-coupleable with a substrate; and
at least one openable portion coupled with said cover element, said openable portion adapted to allow access to a portion of said substrate.

2. The substrate cover assembly of claim 1 wherein said openable portion is configured to allow access to said portion of said substrate without removal of said cover element.

3. The substrate cover assembly of claim 1 wherein said openable portion is selected from the group consisting of a hinge portion, a sliding portion, a window portion, or a removable portion.

4. The substrate cover assembly of claim 1 further comprising:
at least one attaching device for removably-coupling said cover element with said substrate.

5. The substrate cover assembly of claim 4 wherein said attaching device is selected from the group consisting of a rivet, screw, snap, or adhesive.

6. The substrate cover assembly of claim 1 wherein said substrate is a printed circuit board (PCB).

7. The substrate cover assembly of claim 1 wherein said cover element is attached to the solder side.

8. The substrate cover assembly of claim 1 wherein said cover element is comprised of material manufactured in accordance with a network equipment building systems (NEBS) standard.

9. The substrate cover assembly of claim 1 wherein said cover element is adapted to be removably-coupleable with said substrate in accordance with a compact peripheral component interconnect (CPCI) standard.

10. The substrate cover assembly of claim 1 wherein said cover element is adapted to be removably-coupleable with said substrate in accordance with a VersaModular Eurocard (VME) standard.

11. A method for allowing a portion of substrate to be accessed when said substrate has a protective cover coupled thereto comprising:
a) providing a removably-coupleable cover element for said substrate;
b) integrating an openable portion with said removably-coupleable cover element such that said openable portion can be operated to allow a user access with a portion of substrate residing thereunder.

12. The method for allowing a portion of substrate to be accessed when said substrate has a protective cover coupled thereto as recited in claim 11 wherein said step b) further comprises providing access to said portion of said substrate via said openable portion without removing said cover element.

13. The method for allowing a portion of substrate to be accessed when said substrate has a protective cover coupled thereto as recited in claim 11 wherein said step b) further comprises selecting said openable portion from the group consisting of a hinge portion, a sliding portion, a window portion, or a removable portion.

14. The method for allowing a portion of substrate to be accessed when said substrate has a protective cover coupled thereto as recited in claim 11 wherein said substrate is a printed circuit board (PCB).

15. The method for allowing a portion of substrate to be accessed when said substrate has a protective cover coupled thereto as recited in claim 11 wherein said step a) further comprises utilizing an attaching device for removably-coupling said cover element with said substrate.

16. The method for allowing a portion of substrate to be accessed when said substrate has a protective cover coupled thereto as recited in claim 15 wherein said attaching device is selected from the group consisting of a rivet, screw, snap, or adhesive.

17. The method for allowing a portion of substrate to be accessed when said substrate has a protective cover coupled thereto as recited in claim 11 wherein said step a) further comprises manufacturing said cover element in accordance with a network equipment building systems (NEBS) standard.

18. The method for allowing a portion of substrate to be accessed when said substrate has a protective cover coupled thereto as recited in claim 11 wherein said step a) further comprises removably-coupling said cover element with said substrate in accordance with the group consisting of compact peripheral component interconnect (CPCI) or VersaModular Eurocard (VME) standard.

19. A solder-side cover assembly comprising:
a cover element adapted to be removably-coupled with a printed circuit assembly (PCA); and
a portion of said cover element adapted to selectively expose a portion of said PCA without removing said cover element.

20. The solder-side cover assembly of claim 19 wherein said portion of said cover element adapted to selectively expose a portion of said PCA is selected from the group consisting of a hinge element, a sliding element, a window element, or a removable element.

21. The solder-side cover assembly of claim 19 wherein said cover element is removably-coupled with said PCA in accordance with the group consisting of compact peripheral component interconnect (CPCI) standard and VersaModular Eurocard (VME) standard.

22. The solder-side cover assembly of claim 19 wherein said cover element and said portion of said cover element adapted to selectively expose a portion of said PCA are comprised of materials manufactured in accordance with a network equipment building systems (NEBS) standard UL94V-0.
